(19) United States
(12) Patent Application Publication
(10) Pub. No.: US 2025/0076405 A1
(43) Pub. Date: Mar. 6, 2025

(54) METHOD AND DEVICE FOR DETERMINING A LOAD INDEX OF A POWER CONVERTER

(71) Applicants: SEMIKRON DANFOSS ELEKTRONIK GMBH & CO., KG, NUREMBERG (DE); SEMIKRON DANFOSS GMBH, FLENSBURG (DE)

(72) Inventors: Roland SCHWARZ, Allersberg (DE); Ralf Ehler, Market Erlbach (DE); Tobias Appel, Krusau (DK); Rudiger Bode, Furth (DE)

(73) Assignees: SEMIKRON DANFOSS ELEKTRONIK GMBH & CO., KG, NUREMBERG (DE); SEMIKRON DANFOSS GMBH, FLENSBURG (DE)

(21) Appl. No.: 18/821,507

(22) Filed: Aug. 30, 2024

(30) Foreign Application Priority Data
Sep. 1, 2023 (DE) 10 2023 123 564.8

(51) Int. Cl. G01R 31/40; B60L 53/22; B60L 53/62; B60L 53/68

(52) U.S. Cl. CPC G01R 31/40; B60L 53/22; B60L 53/62; B60L 53/68

(57) ABSTRACT

A device and a method for determining a load index of a power converter as part of a charging device for electrically operated vehicles. Included is a power converter which has power electronics switching equipment and a control device for controlling this, wherein a logging device stores a plurality, preferably at least three, particularly at least five, of characteristics of the charging device and in particular of the power converter, having an evaluation device, which evaluates the plurality of characteristics and determines the load index therefrom and, when a first threshold value of the load index is reached, transmits this information about this to a first superordinate decision device.

### CROSS REFERENCE TO RELATED APPLICATIONS

This application relates to and claims priority to DE 10 2023 123 564.8 filed Sep. 1, 2023, the entire contents of which are incorporated herein fully by reference.

### FIGURE SELECTED FOR PUBLICATION

FIG. 1.

### BACKGROUND OF THE INVENTION

### Field of the Invention

The invention describes a method for determining a load index of a power converter as part of a charging device for electrically operated vehicles. The invention furthermore describes a device for carrying out this method, wherein a logging device has a data storage device and wherein an evaluation device has a computing device.

### Description of the Related Art

DE 198 24 064 A1 discloses a circuit arrangement with a detection of all instantaneous operating conditions as parameters, which generates a self-adapting power cut-off threshold from these permanently available values, which operates independently of the higher-level control system, so that a dynamic real-time evaluation of the performance characteristic map takes place and thus currently normalized data about the utilization and load factor are delivered exclusively to the higher-level control system of the controller in the form of a map-orientated overload evaluation. Thus, with an online temperature detection, the power section of each circuit arrangement can be protected completely from thermal overload. To calculate the losses, extensive computing operations are necessary, which cannot be realized economically using analogue circuits. A low-cost microcontroller can be used successfully as a solution for the inventive idea here. A digital data exchange with a controller is possible and as a result detailed error messages with digital actual-value output are possible instead of cumulative error designation.

EP 3 959 100 B1 discloses a method comprising: obtaining historical information of a charging station for electric vehicles; computer-assisted calculation of a first reliability index based on the historical information, wherein the first reliability index corresponds to the reliability of the charging station for electric vehicles during a first time period; computer-assisted calculation of a second reliability index based on the historical information, wherein the second reliability index corresponds to the reliability of the charging station during a second time period; computer-assisted calculation of a third reliability index based on the first reliability index and the second reliability index; and providing the third reliability index for a user; wherein the calculation of the first/second reliability index based on the historical information comprises: assigning points to at least one reliability indicator based on the historical information; and calculating the first/second reliability index based on the assigned points; wherein the at least one reliability indicator comprises at least a number of charges performed.

### ASPECTS AND OBJECTS OF THE INVENTION

At least one of the objects of the present invention is to provide an improvement over the related art.

Knowing the aforementioned, the invention is based on the object of providing an improved and expanded method and an associated device for determining a load index of a power converter.

This object is achieved according to the invention by a method for determining a load index of a power converter as part of a charging device for electrically operated vehicles, having a power converter which has power electronics switching equipment and a control device for this, wherein a logging device stores a plurality, that is to say at least three, particularly at least five, of characteristics of the charging device and in particular of the power converter, having an evaluation device, which evaluates the plurality of characteristics and determines the load index therefrom and, when a first threshold value of the load index is reached, transmits this information about this to a first superordinate decision device.

It is preferred if the characteristics are selected in particular from among:
a. a time curve of the voltage at the input 20 of the power converter 2;
b. a time curve of the current at the input 20 of the power converter 2;
c. an electrical system utilization;
d. a number of charging processes;
e. a duration of the individual charging process;
f. a time curve of the charging current of the respective charging process;
g. a time curve of the charging voltage of the respective charging process;
h. an overvoltages inside the power electronics circuit;
i. a temperature of components of the power converter;
j. a dynamic pressure of a cooling device;
k. a temperature at the output of the cooling device;
l. a speed of a fan of the cooling device;
m. an ambient temperature;
n. a relative air humidity of the environment; and
o. a particulate matter concentration of the environment.

It may be advantageous if this information is transmitted to a second superordinate decision device when a second threshold value of the load index is reached.

It may furthermore be advantageous if the data of the logging device are transmitted in a complete or selected manner to a third superordinate decision device.

It may also be advantageous if the respective evaluations of the evaluation device are transmitted in a complete or selected manner to a fourth superordinate decision device.

Each of these evaluation devices can be localized at a different location. It may also be preferred that at least two of these evaluation devices coincide, that is to say are localized at the same location and preferably are even identical.

It is preferred if the evaluation device determines the characteristics, particularly differently in each case, in a weighted manner for a respective value of the load index. To this end, from N characteristics, an M-tuple can be determined as value of the load index, wherein M is smaller than or equal to N. Furthermore, individual characteristics can flow multiple times and preferably in a differently weighted manner into one or more components of the M-tuple.

It may be particularly preferred if the weighting of the respective characteristics during operation is externally parametrized. Alternatively or additionally, it may be preferred if the weighting of the respective characteristics during operation is parametrized by the evaluation device itself.

It may also be advantageous if the evaluation device determines the load index from additional data of other power converters. To this end, the decision device can provide the data of other power converters to the evaluation device.

In particular, it may be advantageous if the data of other power converters flow into the parametrization.

Fundamentally, it is preferred if the decision device has a reactive effect on an activation device and its activation behavior (activation control) of the power converter is changed hereby.

The object is furthermore achieved by a device for carrying out the aforementioned method, having a power converter as part of a charging device for electrically operated vehicles, wherein the power converter has power electronics switching equipment and a control device for this, wherein a logging device has a data storage device, wherein an evaluation device has a computing device and wherein a superordinate decision device has a data transmission device.

It is advantageous if the charging device has the decision device.

It is preferred if the decision device is not designed as part of the charging device, but rather is connected to the charging device by means of a data connection, preferably a cloud connection.

It is understood that the various embodiments of the invention can be realized individually or in any desired combinations, in order to achieve improvements. In particular, the features which are mentioned and explained above and in the following can be used not only in the specified combinations, but also in other combinations or alone, without departing from the scope of the present invention and independently of whether they are disclosed in the context of the method or the device.

Further explanations of the invention, advantageous details and features are to be found in the following description of the exemplary embodiments of the invention, which are illustrated schematically in the figures or in respective parts thereof.

The above and other aspects, features, objects, and advantages of the present invention will become apparent from the following description read in conjunction with the accompanying drawings for exemplary but nonlimiting embodiments, in which like reference numerals designate the same elements.

### BRIEF DESCRIPTION OF THE DRAWINGS

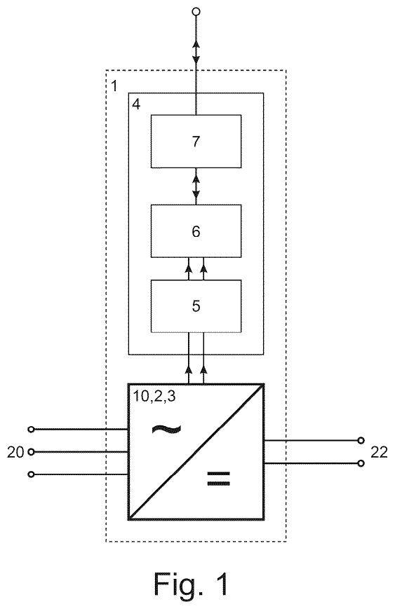

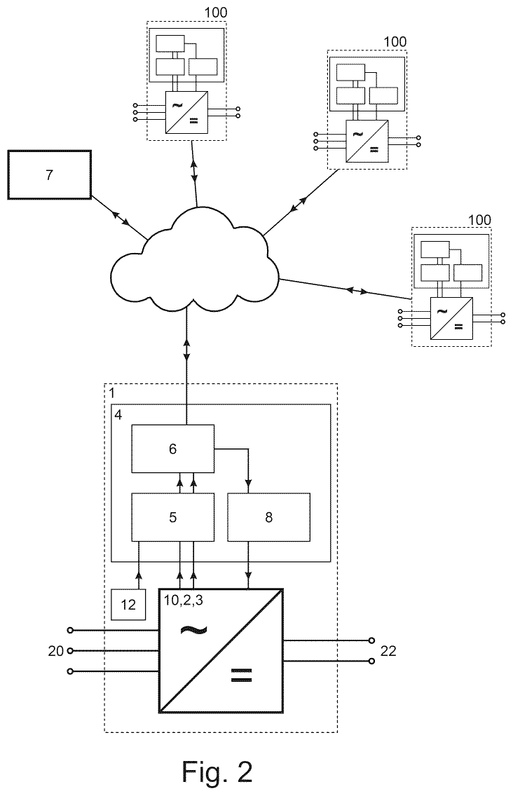

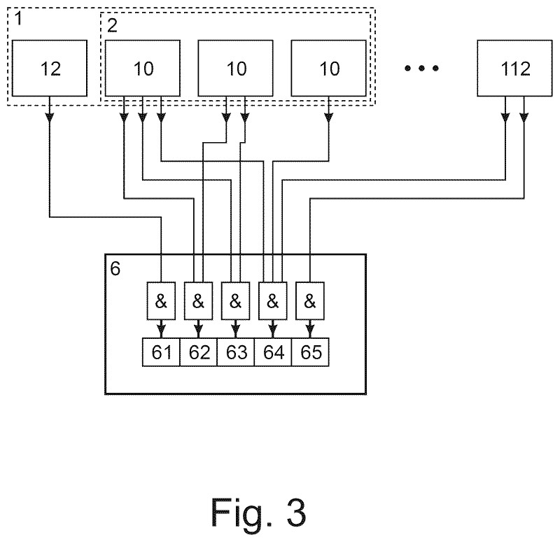

FIG. 1 shows a first embodiment of a device according to the invention.

FIG. 2 shows a second embodiment of a device according to the invention and further components connected in terms of process engineering to the device in the context of the method according to the invention.

FIG. 3 shows a core aspect of the method according to the invention.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ or ‘bond’ or and similar terms do not necessarily denote direct and immediate connections, but also include connections through intermediate elements or devices. For purposes of convenience and clarity only, directional (up/down etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

FIG. 1 shows a first embodiment of a device according to the invention. A power converter 2 is illustrated as part of a charging device 1 for electrically operated vehicles, particularly road vehicles. The power converter 2 is here designed in a simplified manner as power electronics switching equipment 3 having a rectifier which is supplied with power, at its input 20 purely by way of example, from an AC voltage supply system and which outputs a direct current at its output 22. Here, the rectifier may in particular have components for galvanic isolation and for increasing the voltage at its output 22.

The power converter 2 has a plurality of sensor devices 10, which by way of example sense the temperature of components of the power converter 2, more precisely its power electronics switching equipment 3. Furthermore, the power converter 2, more precisely its control device, has a sensor device 10 for determining the charging current. From sensor data of this type, which are stored in a logging device 5 of the control device 4, and the activation data for activating the power electronics switching equipment 3, the activation device 6 of the control device 4 determines various characteristics, such as number of charging processes, duration of the individual charging process, time curve of the charging current of the respective charging process, overvoltages inside the power electronics circuit 3 and temperature of components of the power converter 2.

These characteristics are processed in the evaluation device 6 to form a load index. Here, further characteristics, particularly of the environment of the charging device, such as ambient temperature and particulate matter concentration also flow in. These two parameters are important in particular for determining the cooling performance of a cooling device for cooling the power converter. When a first threshold value of the load index is reached, this information is transmitted to a first superordinate decision device 7 which is an integral constituent of the charging device 1 here. The decision device 7 determines a reaction from this, which can be designed by way of example as a reduction of the charging power or as a requirement for maintenance.

FIG. 2 shows a second embodiment of a device according to the invention and further components connected in terms of process engineering to the device in the context of the method according to the invention. A power converter 2 is in turn illustrated as part of a charging device 1 for electrically operated vehicles, wherein the actual embodiment of the power electronics switching equipment is fundamentally not relevant.

The logging device 5 is important, which stores a plurality of characteristics which are based on sensor evaluations and on evaluations of the operating states of the power converter 2.

The evaluation device determines, cf. also FIG. 3, a respective value of the load index from these characteristics. Essentially, all characteristics can to this end be weighted differently. Also, individual characteristics can be included in the weighting multiple times, that is to say are parametrized.

Furthermore, a data connection is illustrated, particularly a cloud connection to a decision device 7 which is not an integral constituent of the charging device 1. By way of example, the decision device 1 can be localized at the manufacturer of the charging device, at the operator of the charging device or at the manufacturer of the power converter or in each case be operated by the same.

The weighting of the respective characteristics can be parametrized during operation. Here, it is advantageous if the parameters of the weighting are transmitted from the decision device 7 to the evaluation device 6 or more generally to the control device 4. A change of the parameters of the weighting can however also take place particularly efficiently and fast by means of the evaluation device 7 or the control device 4 itself. To this end, the evaluation device 7 or the control device 4 has a corresponding algorithm implemented there.

In addition, it is particularly efficient if the parameters of the weighting by means of the evaluation device 7 are adapted not only on the basis of data of the charging device, but additionally parameters for determining the load index from additional data of other power converters and therefore other charging devices 100 are also taken into consideration. To this end, the decision device 7 can provide the data of other power converters and therefore other charging devices 100 to the evaluation device 6.

An important advantage results from the decision device 7 having a direct or indirect reactive effect on an activation device 8 of the power converter 2. Thereby, the activation behavior of the power converter 2 can be changed compared to a basic setting during operation by way of example, as a result of which it is possible by way of example to react to functional limitations of other power converters in further charging devices 100 so early by means of certain characteristics that the fault at the power converter 2 does not occur or occurs in a delayed manner.

FIG. 3 shows a core aspect of the method according to the invention. A plurality of sensors 10, which are arranged in the power converter 2, are illustrated purely by way of example, a sensor 12 which is arranged in the charging device 1 outside of the power converter 2 (cf. FIG. 2) and a further sensor 112 which is arranged in a further charging device 100. These sensors deliver characteristics to the logging device 5 which is not explicitly illustrated.

The characteristics stored in the logging device are processed in the evaluation device 6. To this end, various characteristics are evaluated individually and stored in an assigned component of a 5-tuple, which is exemplary here. Some characteristics are stored together with other characteristics in assigned components of the 5-tuple. This 5-tuple (61, 62, 63, 64, 65) forms a value of the load index of the power converter 2 of the charging device 1.

As soon as a component or a selection of a plurality of components exceeds a provided first threshold value, this exceeding is transmitted to the superordinate decision device 7.

On the basis of this transmission and in particular with inclusion of load indices of a further charging device 1, if required, the decision device 7 initiates a change of the weightings of one or more characteristics by means of a data transmission device.

Thus, during operation, that is to say the entire service life of the charging device 1, the weighting of the characteristics can be parametrized, that is to say changed. Thus, the power converter, particularly its output power, can be adjusted always and if required only temporarily, for example if the supplying power system is overloaded.

Alternatively or additionally, maintenance or even a replacement of the power converter 2 or the charging device 1 in general can occur on the basis of the aforementioned transmission.

The decision device therefore has a learning algorithm which externally and, alternatively or additionally, also independently performs a parametrization of the weighting of characteristics of the charging device 1 and the power converter 2.

Also, the inventors intend that only those claims which use the specific and exact phrase “means for” are intended to be interpreted under 35 USC 112. The structure, device, and arrangement herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure covers modifications and variations of this disclosure provided they come within the scope of the appended claims and their equivalents.

What is claimed is:

1. A method for determining a load index of a power converter (2), as part of a charging device (1) for electrically operated vehicles, comprising the steps of:
providing said power converter (2) having power electronics switching equipment (3) and a control device (4) that controls said power converter (2);
providing a logging device (5) in said control device (4),
wherein said logging device (5) stores a plurality of characteristics of the charging device (1) and of the power converter (2);
providing an evaluation device (6) in said control device (4),
wherein said evaluation device (6) evaluates the plurality of characteristics of the charging device (1) and determines the load index therefrom and, when a first threshold value of the load index is reached, transmits an information about this to a first superordinate decision device (7).

2. The method, according to claim 1, wherein:
the plurality characteristics are selected from the group consisting of,
a time curve of a voltage at an input (20) of the power converter (2),
a time curve of a current at the input (20) of the power converter (2),
an electrical system utilization,
a number of charging processes,
a duration of the individual charging process,
a time curve of the charging current of the respective charging process,
a time curve of the charging voltage of the respective charging process,
an overvoltage inside a power electronics circuit,
a temperature of components of the power converter,
a dynamic pressure of a cooling device,
a temperature at an output of the cooling device,
a speed of a fan of the cooling device,
an ambient temperature,
a relative air humidity of the environment, and
a particulate matter concentration of the environment.

3. The method, according to claim 2, wherein:
the information is transmitted to a second superordinate decision device when a second threshold value of the load index is reached.

4. The method, according to claim 2, wherein:
the data of the logging device (5) are transmitted in a complete or a selected manner to a third superordinate decision device.

5. The method, according to claim 2, wherein:
the respective evaluations of the evaluation device (6) are transmitted in a complete or selected manner to a fourth superordinate decision device.

6. The method, according to claim 2, wherein:
the evaluation device (6) determines the characteristics, particularly differently in each case, in a weighted manner for a respective value of the load index.

7. The method, according to claim 6, wherein:
from N characteristics, an M-tuple (61, 62, . . . , 6M) can be determined as a value of the load index, wherein M is smaller than or equal to N.

8. The method, according to claim 7, wherein:
individual characteristics can flow multiple times and in a differently weighted manner into one or more components of the M-tuple (61, 62, . . . , 6M).

9. The method, according to claim 8, wherein:
the weighting of the respective characteristics during operation is externally parametrized.

10. The method, according to claim 9, wherein:
the weighting of the respective characteristic during operation is parametrized by the evaluation device (7) itself.

11. The method, according to claim 10, wherein:
the evaluation device (7) determines the load index from additional data of other power converters or other charging devices (100).

12. The method, according to claim 11, wherein:
the decision device (7) provides the data of other power converters or other charging devices (100) to the evaluation device (6).

13. The method, according to claim 12, wherein:
the data of the other power converters or the other charging devices (100) flow into the parametrization.

14. The method, according to claim 13, wherein:
the first superordinate decision device (7) has a reactive effect on an activation device (8) and its activation control of the power converter (2) is changed thereby.

15. A device, for carrying out the method according to claim 1, said device comprising:
said power converter (2) as part of said charging device (1) for electrically operated vehicles, wherein the power converter (2) has power electronics switching equipment (3) and said control device (4);
wherein said logging device (5) has a data storage device;
wherein said evaluation device (6) has a computing device; and
wherein said first superordinate decision device (7) further comprises,
a data transmission device.

16. The device, according to claim 15, wherein:
the charging device (1) has the decision device (7).

17. The device, according to claim 15, wherein:
the decision device (7) is not designed as part of the charging device (1), but rather is connected to the charging device (1) by means of a data connection, including a cloud connection.
